(19) United States
(12) Patent Application Publication
(10) Pub. No.: US 2025/0239558 A1
(43) Pub. Date: Jul. 24, 2025

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Ra-Min Tain, Hsinchu County (TW); Chih-Kai Chan, Taoyuan City (TW); Shih-Lian Cheng, New Taipei City (TW); Guang-Hwa Ma, Hsinchu City (TW)

(73) Assignee: Unimicron Technology Corp., Taoyuan City (TW)

(21) Appl. No.: 18/764,163

(22) Filed: Jul. 4, 2024

Related U.S. Application Data
(60) Provisional application No. 63/623,825, filed on Jan. 23, 2024.

(30) Foreign Application Priority Data
May 21, 2024 (TW) 113118680

(51) Int. Cl. H01L 23/00; H01L 23/495; H01L 29/34

(52) U.S. Cl. CPC H01L 24/32; H01L 23/49582; H01L 24/29; H10D 62/57; H01L 2224/29016; H01L 2224/29187; H01L 2224/32155; H01L 2924/15788

(57) ABSTRACT

A substrate structure includes an inorganic substrate, an adhesion promotion layer (APL), an electroless nickel-phosphor layer, and a conductive material. The inorganic substrate has an upper surface, a lower surface, and at least one through hole. The APL is disposed on the upper surface, the lower surface, and an inner wall of the at least one through hole. The electroless nickel-phosphor layer is disposed on a portion of the APL. The conductive material is disposed on the electroless nickel-phosphor layer and fills the at least one through hole to define at least one first conductive circuit on the upper surface, at least one second conductive circuit on the lower surface and at least one conductive through hole located within the at least one through hole and electrically connected to the at least one first conductive circuit and the at least one second conductive circuit.

### CROSS-REFERENCE TO RELATED APPLICATION

This application claims the priority benefit of U.S. provisional application Ser. No. 63/623,825, filed on Jan. 23, 2024, and Taiwan application serial no. 113118680, filed on May 21, 2024. The entirety of each of the above-mentioned patent applications is hereby incorporated by reference herein and made a part of this specification.

### BACKGROUND

### Technical Field

The disclosure relates to a substrate structure and a manufacturing method thereof, and in particular to a substrate structure having a conductive through hole and a manufacturing method thereof.

### Description of Related Art

Generally, due to an adhesion problem between an inorganic substrate and a metal layer, the metal layer is deposited on the inorganic substrate by dry deposition (such as physical vapor deposition (PVD) or chemical vapor deposition (CVD)). However, using dry deposition to form the metal layer is expensive, and blind holes and through holes with high aspect ratios often face a problem of low step coverage during the dry deposition process, thereby increasing process defects and reducing product reliability.

### SUMMARY

The disclosure provides a substrate structure and a manufacturing method thereof, which can reduce production costs and improve product reliability.

The substrate structure of the disclosure includes an inorganic substrate, an adhesion promotion layer, an electroless nickel-phosphor layer, and a conductive material. The inorganic substrate has an upper surface and a lower surface opposite to each other and at least one through hole penetrating the inorganic substrate and connected to the upper surface and the lower surface. The adhesion promotion layer is disposed on the upper surface, the lower surface, and an inner wall of the at least one through hole of the inorganic substrate. The electroless nickel-phosphor layer is disposed on a portion of the adhesion promotion layer. The conductive material is disposed on the electroless nickel-phosphor layer and fills the at least one through hole to define at least one first conductive circuit located on the upper surface, at least one second conductive circuit located on the lower surface, and at least one conductive through hole located within the at least one through hole and electrically connected to the at least one first conductive circuit and the at least one second conductive circuit.

In an embodiment of the disclosure, a material of the inorganic substrate includes glass or ceramics.

In an embodiment of the disclosure, a surface roughness of the inorganic substrate is between 1 nm and 50 nm.

In an embodiment of the disclosure, a thickness of the inorganic substrate is between 50 μm and 1000 μm.

In an embodiment of the disclosure, a diameter of the at least one through hole is between 10 μm and 200 μm.

In an embodiment of the disclosure, a material of the adhesion promotion layer includes an oxide or a nitride.

In an embodiment of the disclosure, a thickness of the adhesion promotion layer is between 0.01 nm and 100 nm.

In an embodiment of the disclosure, the substrate structure further includes an electroless copper layer, disposed between the electroless nickel-phosphor layer and the conductive material.

In an embodiment of the disclosure, the substrate structure further includes at least one build-up structure, disposed on at least one of the upper surface and the lower surface of the inorganic substrate. The at least one build-up structure includes at least one insulating layer, at least one conductive blind hole, and at least one trace. The at least one insulating layer covers at least one of the at least one first conductive circuit and the at least one second conductive circuit. The at least one trace is located on the at least one insulating layer. The at least one conductive blind hole is located within the at least one insulating layer and electrically connected to the at least one trace and at least one of the at least one first conductive circuit and the at least one second conductive circuit.

A manufacturing method of a substrate structure of the disclosure includes following steps: providing an inorganic substrate, where the inorganic substrate has an upper surface and a lower surface opposite to each other and at least one through hole penetrating the inorganic substrate and connected to the upper surface and the lower surface; forming an adhesion promotion layer on the upper surface, the lower surface, and an inner wall of the at least one through hole of the inorganic substrate; performing a wet process on the inorganic substrate to form an electroless nickel-phosphor layer on the adhesion promotion layer; forming a conductive material on the electroless nickel-phosphor layer and filling the at least one through hole to define at least one conductive through hole within the at least one through hole; and patterning the conductive material and the electroless nickel-phosphorus layer to define at least one first conductive circuit on the upper surface and at least one second conductive circuit on the lower surface, where the at least one conductive through hole is electrically connected to the at least a first conductive circuit and at least one second conductive circuit.

Based on the above, the substrate structure and the manufacturing method thereof in the disclosure increases the adhesion between the inorganic substrate and the metal layer by the adhesion promotion layer and forms the electroless nickel-phosphor layer on the adhesion promotion layer by performing the wet process, thereby solving the problem of low step coverage in the dry deposition process of the existing technology and reducing production costs to improve product reliability.

In order to make the aforementioned features and advantages of the disclosure comprehensible, embodiments accompanied with drawings are described in detail below.

### BRIEF DESCRIPTION OF THE DRAWINGS

FIG. 1A to FIG. 1D are schematic cross-sectional views of a manufacturing method of a substrate structure according to an embodiment of the disclosure.

FIG. 2 is a schematic cross-sectional view of a substrate structure according to an embodiment of the disclosure.

FIG. 3 is a schematic cross-sectional view of a substrate structure according to another embodiment of the disclosure.

### DESCRIPTION OF THE EMBODIMENTS

The embodiments of the disclosure may be understood together with the drawings, and the drawings of the disclosure are also regarded as portion of the disclosure description. It should be understood that the drawings of the disclosure are not drawn to scale and, in fact, the dimensions of elements may be arbitrarily enlarged or reduced in order to clearly represent the features of the disclosure.

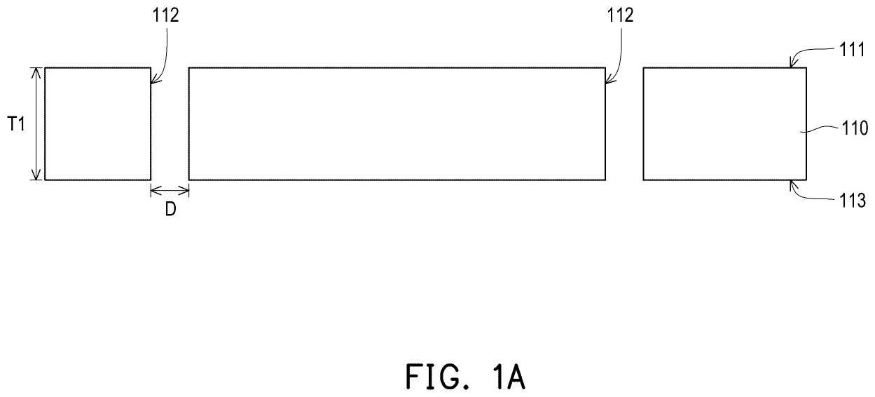

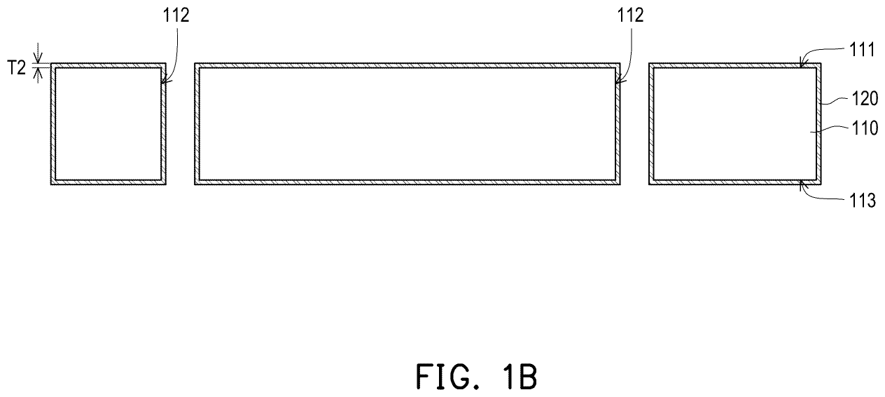

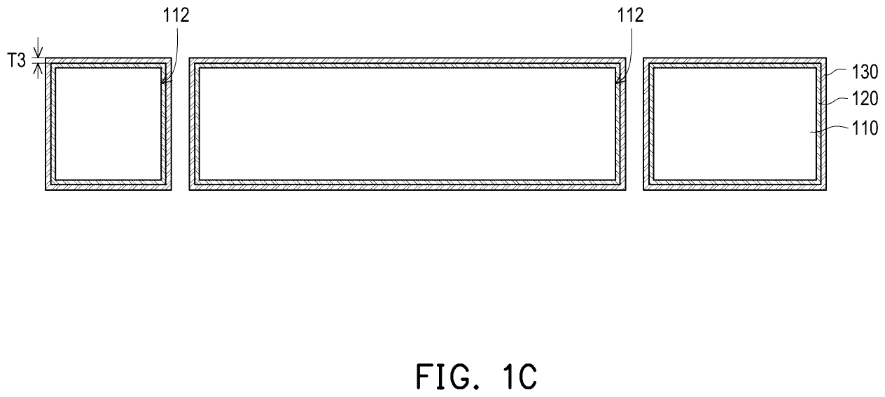

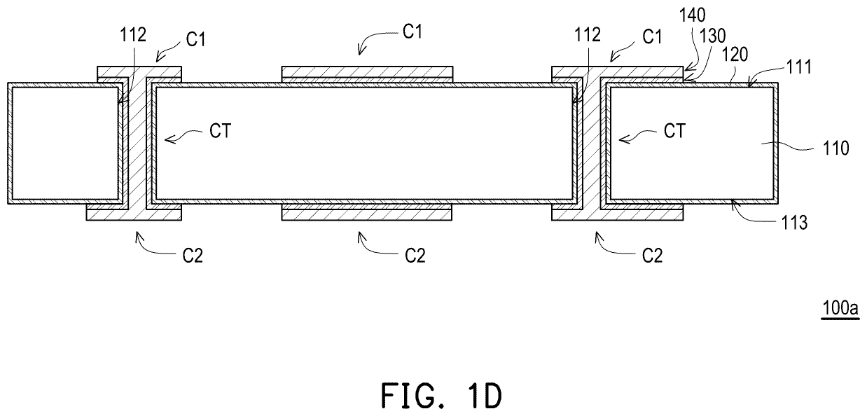

FIG. 1A to FIG. 1D are schematic cross-sectional views of a manufacturing method of a substrate structure according to an embodiment of the disclosure. According to the manufacturing method of the substrate structure of this embodiment, with reference to FIG. 1A at first, an inorganic substrate 110 is provided. The inorganic substrate 110 has an upper surface 111 and a lower surface 113 opposite to each other, and at least one through hole (two through holes 112 are schematically shown) penetrating the inorganic substrate 110 and connected to the upper surface 111 and the lower surface 113. In an embodiment, the inorganic substrate 110 is an insulating substrate, but is not limited thereto. In an embodiment, a material of the inorganic substrate 110 is, for example, glass or ceramic, but is not limited thereto. In this embodiment, a surface roughness of the inorganic substrate 110, such as arithmetic average roughness (Ra), is between 1 nm and 50 nm, for example. A thickness T1 of the inorganic substrate 110 is, for example, between 50 μm and 1000 μm, preferably between 100 μm and 800 μm. The through hole 112 is embodied as a glass through hole (TGV), where a diameter D of the through hole 112 is, for example, between 10 μm and 200 μm, preferably between 100 μm and 200 μm.

Next, with reference to FIG. 1B, an adhesion promotion layer 120 is formed on the upper surface 111, the lower surface 113, and the inner wall of the through hole 112 of the inorganic substrate 110 by dry deposition, but is not limited thereto. Here, the adhesion promotion layer 120 completely covers the upper surface 111, the lower surface 113, and the inner wall of the through hole 112 of the inorganic substrate 110. In an embodiment, a material of the adhesion promotion layer 120 is, for example, an oxide or a nitride. The oxide is, for example, titanium oxide (TiOₓ) (such as titanium monoxide (TiO) or titanium dioxide (TiO₂)), silicon oxide (SiOₓ) (such as silicon dioxide (SiO₂)) or aluminum oxide (Al₂O₃), and the nitride is, for example, silicon nitride (SiNₓ) (such as silicon nitride (Si₃N₄)). In this embodiment, a thickness T2 of the adhesion promotion layer 120 is, for example, between 0.01 nm and 100 nm, where the adhesion promotion layer 120 may increase the adhesion between the inorganic substrate 110 and the subsequently formed metal layer.

Next, with reference to FIG. 1C, a wet process is performed on the inorganic substrate 110 to form an electroless nickel-phosphor layer 130 on the adhesion promotion layer 120. Here, the electroless nickel-phosphor layer 130 completely covers the adhesion promotion layer 120. In an embodiment, a thickness T3 of the electroless nickel-phosphor layer 130 is, for example, greater than 0 and less than 1 micron.

Afterwards, with reference to FIG. 1D, the electroless nickel-phosphor layer 130 is used as an electroplating seed layer. A conductive material 140 is formed on the electroless nickel-phosphor layer 130 by an electroplating method and fills the through hole 112 to define at least one conductive through hole (two conductive through holes CTs are schematically shown) within the through hole 112.

Finally, with reference to FIG. 1D again, the conductive material 140 and the electroless nickel-phosphor layer 130 are patterned to define at least one first conductive circuit (three first conductive circuits C1 are schematically shown) on the upper surface 111 and at least one second conductive circuit (three second conductive circuits C2 are schematically shown) on the lower surface 113. The conductive through hole CT is electrically connected to the first conductive circuit C1 and the second conductive circuit C2. At this point, the production of the substrate structure 100a has been completed.

Structurally, with reference to FIG. 1D again, the substrate structure 100a includes the inorganic substrate 110, the adhesion promotion layer 120, the electroless nickel-phosphor layer 130, and the conductive material 140. The inorganic substrate 110 has the upper surface 111 and the lower surface 113 opposite to each other, and the through hole 112 penetrating the inorganic substrate 110 and connected to the upper surface 111 and the lower surface 113. The adhesion promotion layer 120 is disposed on the upper surface 111, the lower surface 113, and on the inner wall of the through hole 112 of the inorganic substrate 110. The electroless nickel-phosphor layer 130 is disposed on a portion of the adhesion promotion layer 120, which means that the electroless nickel-phosphor layer 130 does not completely cover the adhesion promotion layer 120, but exposes another portion of the adhesion promotion layer 120. The conductive material 140 is disposed on the electroless nickel-phosphor layer 130 and fills the through hole 112 to define the first conductive circuit C1 located on the upper surface 111, the second conductive circuit C2 located on the lower surface 113, and the conductive through hole CT located within the through hole 112 and electrically connected to the first conductive circuit C1 and the second conductive circuit C2.

In short, this embodiment increases the adhesion between the inorganic substrate 110 and the metal layer (such as the electroless nickel-phosphor layer 130 and the conductive material 140) by the adhesion promotion layer 120, and forms the electroless nickel-phosphor layer 130 on the adhesion promotion layer 120 by performing the wet process, thereby solving a problem of low step coverage in the dry deposition process of the existing technology and reducing production costs of the substrate structure 100a of this embodiment to improve product reliability.

Other embodiments are listed below for description. It must be noted here that the following embodiments adopt the reference numerals and part of the content of the above embodiments, wherein the same reference numerals are used to represent the same or similar elements, and the description of the same technical content is omitted. For the description of the omitted parts, reference may be made to the above embodiments, which is not repeated in the following embodiments.

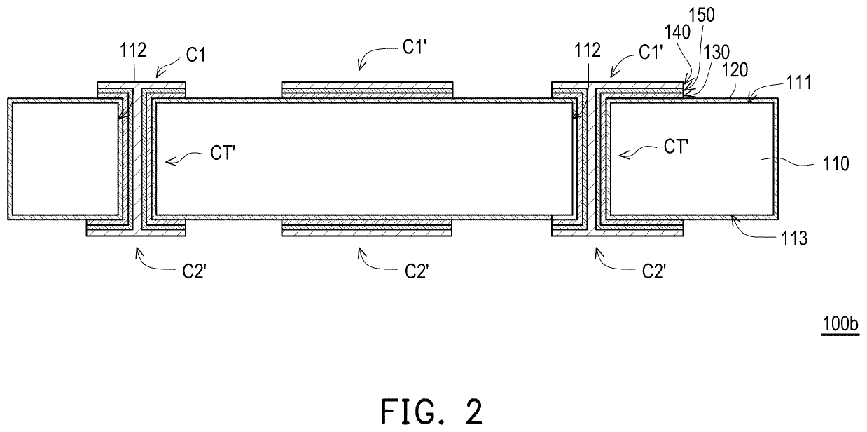

FIG. 2 is a schematic cross-sectional view of a substrate structure according to an embodiment of the disclosure. With reference to FIG. 1D and FIG. 2 together, a substrate structure 100b of this embodiment is similar to the aforementioned substrate structure 100a. The main difference between the two lies in that: in this embodiment, the substrate structure 100b further includes an electroless copper layer 150 disposed between the electroless nickel-phosphor layer 130 and the conductive material 140. The bonding between the electroless nickel-phosphor layer 130 and the adhesion promoting layer 120 is better than the bonding between the electroless copper layer 150 and the adhesion promoting layer 120, which may improve reliability.

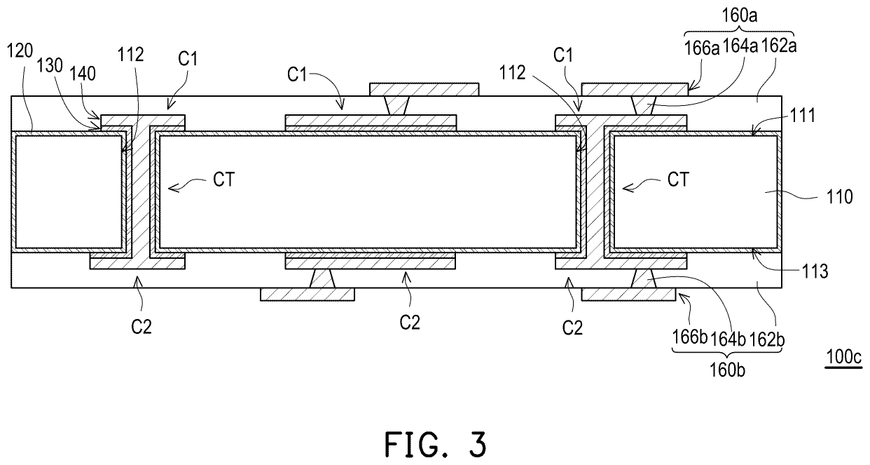

FIG. 3 is a schematic cross-sectional view of a substrate structure according to another embodiment of the disclosure. With reference to FIG. 1D and FIG. 3 together, a substrate structure 100c of this embodiment is similar to the aforementioned substrate structure 100a. The main difference between the two lies in that: in this embodiment, the substrate structure 100c further includes at least one build-up structure (two build-up structures 160a and 160b are schematically shown), where the built-up structures 160a and 160b are respectively disposed on the upper surface 111 and lower surface 113 of the inorganic substrate 110. Specifically, the build-up structure 160a includes at least one insulating layer (one insulating layer 162a is schematically shown), at least one conductive blind hole (two conductive blind holes 164a are schematically shown), and at least one trace (two traces 166a are schematically shown). The insulating layer 162a covers the first conductive circuit C1, the trace 166a is located on the insulating layer 162a, and the conductive blind hole 164a is located within the insulating layer 162a and electrically connected to the trace 166a and the first conductive circuit C1. Similarly, the build-up structure 160b includes at least one insulating layer (one insulating layer 162b is schematically shown), at least one conductive blind hole (two conductive blind holes 164b are schematically shown), and at least one trace (two traces 166b are schematically shown). The insulating layer 162b covers the second conductive circuit C2, the trace 166b is located on the insulating layer 162b, and the conductive blind hole 164b is located within the insulating layer 162b and electrically connected to the trace 166b and the second conductive circuit C2. A fan-out structure may be formed by disposing the build-up structures 160a and 160b, thereby increasing the applicability of the substrate structure 100c.

In summary, the substrate structure and the manufacturing method thereof in the disclosure increases the adhesion between the inorganic substrate and the metal layer by the adhesion promotion layer and forms the electroless nickel-phosphor layer on the adhesion promotion layer by performing the wet process, thereby solving the problem of low step coverage in the dry deposition process of the existing technology and reducing production costs to improve product reliability.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A substrate structure, comprising:
an inorganic substrate, having an upper surface and a lower surface opposite to each other and at least one through hole penetrating the inorganic substrate and connected to the upper surface and the lower surface;
an adhesion promotion layer, disposed on the upper surface, the lower surface, and an inner wall of the at least one through hole of the inorganic substrate;
an electroless nickel-phosphor layer, disposed on a portion of the adhesion promotion layer; and
a conductive material, disposed on the electroless nickel-phosphor layer and filling the at least one through hole to define at least one first conductive circuit located on the upper surface, at least one second conductive circuit located on the lower surface, and at least one conductive through hole located within the at least one through hole and electrically connected to the at least one first conductive circuit and the at least one second conductive circuit.

2. The substrate structure according to claim 1, wherein a material of the inorganic substrate comprises glass or ceramics.

3. The substrate structure as described in claim 1, wherein a surface roughness of the inorganic substrate is between 1 nm and 50 nm.

4. The substrate structure according to claim 1, wherein a thickness of the inorganic substrate is between 50 μm and 1000 μm.

5. The substrate structure according to claim 1, wherein a diameter of the at least one through hole is between 10 μm and 200 μm.

6. The substrate structure according to claim 1, wherein a material of the adhesion promotion layer comprises an oxide or a nitride.

7. The substrate structure according to claim 1, wherein a thickness of the adhesion promotion layer is between 0.01 nm and 100 nm.

8. The substrate structure according to claim 1, further comprising:
an electroless copper layer, disposed between the electroless nickel-phosphor layer and the conductive material.

9. The substrate structure according to claim 1, further comprising:
at least one build-up structure, disposed on at least one of the upper surface and the lower surface of the inorganic substrate, wherein the at least one build-up structure comprises at least one insulating layer, at least one conductive blind hole, and at least one trace, the at least one insulating layer covers at least one of the at least one first conductive circuit and the at least one second conductive circuit, the at least one trace is located on the at least one insulating layer, and the at least one conductive blind hole is located within the at least one insulating layer and electrically connected to the at least one trace and at least one of the at least one first conductive circuit and the at least one second conductive circuit.

10. A manufacturing method of a substrate structure, comprising:
providing an inorganic substrate, wherein the inorganic substrate has an upper surface and a lower surface opposite to each other and at least one through hole penetrating the inorganic substrate and connected to the upper surface and the lower surface;
forming an adhesion promotion layer on the upper surface, the lower surface, and an inner wall of the at least one through hole of the inorganic substrate;
performing a wet process on the inorganic substrate to form an electroless nickel-phosphor layer on the adhesion promotion layer;
forming a conductive material on the electroless nickel-phosphor layer and filling the at least one through hole to define at least one conductive through hole within the at least one through hole; and
patterning the conductive material and the electroless nickel-phosphorus layer to define at least one first conductive circuit on the upper surface and at least one second conductive circuit on the lower surface, wherein the at least one conductive through hole is electrically connected to the at least a first conductive circuit and at least one second conductive circuit.
